(19) United States
(12) Patent Application Publication
(10) Pub. No.: US 2015/0114440 A1
(43) Pub. Date: Apr. 30, 2015

(54) THERMOELECTRIC MODULE, METHOD FOR OPERATING THE THERMOELECTRIC MODULE, THERMOELECTRIC GENERATOR AND MOTOR VEHICLE

(71) Applicant: EMITEC GESELLSCHAFT FUER EMISSIONSTECHNOLOGIE MBH, LOHMAR (DE)

(72) Inventors: ROLF BRUECK, BERGISCH GLADBACH (DE); SIGRID LIMBECK, MUCH (DE)

(21) Appl. No.: 14/562,949

(22) Filed: Dec. 8, 2014

Related U.S. Application Data
(63) Continuation of application No. PCT/EP2013/060765, filed on May 24, 2013.

(30) Foreign Application Priority Data
Jun. 6, 2012 (DE) 102012104927.0

(51) Int. Cl. H01L 35/32

(52) U.S. Cl. CPC H01L 35/32
USPC 136/201; 136/205

(57) ABSTRACT

A thermoelectric module includes at least mutually opposite first and second walls and elements made of thermoelectric material disposed therebetween. A filler material spaces all of the elements apart from one another and a main heat flow direction extends from the first wall to the second wall. A method for operating the thermoelectric module, a thermoelectric generator and a motor vehicle are also provided.

### CROSS-REFERENCE TO RELATED APPLICATION

This is a continuation, under 35 U.S.C. §120, of copending International Application No. PCT/EP2013/060765, filed May 24, 2013, which designated the United States; this application also claims the priority, under 35 U.S.C. §119, of German Patent Application DE 10 2012 104 927.0, filed Jun. 6, 2012; the prior applications are herewith incorporated by reference in their entirety.

### BACKGROUND OF THE INVENTION

### Field of the Invention

The present invention relates to a thermoelectric module, a method for operating the thermoelectric module, a thermoelectric generator and a motor vehicle.

Thermoelectric modules can be used individually or in large numbers as a thermoelectric generator which generates electrical energy from a temperature potential and from a resulting heat flow. The electrical energy is generated on the basis of the so-called Seebeck effect. Thermoelectric modules are constructed from electrically interconnected p-doped and n-doped thermoelectric materials. The thermoelectric materials have a so-called hot side and an oppositely disposed cold side by which they are connected, in each case in electrically conductive fashion and in alternating fashion to adjacently disposed further thermoelectric materials. In that case, the hot side is connected in thermally conductive fashion to a wall of a thermoelectric module, in which the wall is impinged on by a hot medium. Correspondingly, the cold side of the thermoelectric material is connected in thermally conductive fashion to another wall of the thermoelectric module, in which the other wall is impinged on by a cold medium.

Such thermoelectric generators are used, in particular, in motor vehicles but also in other technical fields in which a temperature potential can be utilized, through the configuration of thermoelectric generators, for the generation of electrical energy.

In the use of thermoelectric generators, a drop in efficiency with regard to the conversion of thermal energy into electrical energy is commonly observed over the service life of the thermoelectric generator. That wear phenomenon that occurs during operation can be attributed, in particular, to the fact that the connections between the thermoelectric material and further connecting layers to a first wall and/or to a second wall of a thermoelectric module progressively deteriorate. That degradation of the thermally conductive and/or electrically conductive connections is caused, in particular, by the fact that the thermoelectric module is subjected to regularly fluctuating or varying temperatures and temperature potentials. The thermoelectric module is correspondingly loaded by fluctuating thermal expansions and resulting thermal stresses. Furthermore, the loading is intensified by different coefficients of thermal expansion in the individual connecting layers.

### SUMMARY OF THE INVENTION

It is accordingly an object of the invention to provide a thermoelectric module, a method for operating the thermoelectric module, a thermoelectric generator and a motor vehicle, which overcome the hereinafore-mentioned disadvantages and at least partially solve the highlighted problems of the heretofore-known devices and methods of this general type. In particular, it is sought to specify a thermoelectric module which exhibits uniformly high efficiency in the conversion of thermal energy into electrical energy over a long service life. Furthermore, it is sought to specify a method for operating a thermoelectric module which likewise makes it possible to realize a lengthened service life of a thermoelectric module without efficiency being progressively reduced.

With the foregoing and other objects in view there is provided, in accordance with the invention, a thermoelectric module, comprising at least a first wall and an oppositely disposed second wall and interposed elements which are composed of thermoelectric material and which are connected to one another in electrically conductive fashion. Furthermore, a filler material is provided through the use of which all of the elements are spaced apart from one another. In this case, a main heat flow direction runs from a hot side, formed by the first wall, to the second wall. It is provided that, during the operation of the thermoelectric module, at least in a temperature range between 50 and 600° C. [degrees Celsius] at the hot side, a second compressive stress acting on the elements in the main heat flow direction does not exceed at least a first threshold stress or does not exceed at least a second threshold stress. The first threshold stress is a (temperature-dependent) characteristic of the elements composed of thermoelectric material, upon exceeding which a transverse contraction of the thermoelectric material that is used commences. The second threshold stress is a (temperature-dependent) characteristic of the elements composed of thermoelectric material, upon exceeding which a plastic deformation of the thermoelectric material that is used commences.

In particular, when the second threshold stress is reached, a transverse contraction of the thermoelectric material has already commenced.

With the objects of the invention in view, there is also provided a thermoelectric module, comprising at least a first wall and an oppositely disposed second wall and interposed elements which are composed of thermoelectric material, wherein the thermoelectric materials are connected to one another in electrically conductive fashion. Furthermore, a filler material is provided through the use of which all of the elements are spaced apart from one another. A main heat flow direction runs from the first wall to the second wall. The thermoelectric module is braced by at least one compressive force in such a way that, at least in a range in which a temperature potential between the first wall and the second wall is at least 50 Kelvin, in particular at least 200 Kelvin, a first compressive stress perpendicular to the main heat flow direction is at least 50% of a second compressive stress in the main heat flow direction, in particular at least 75%, and preferably at least equal to the second compressive stress (greater than 100%). In particular, the first compressive stress (and preferably also the second compressive stress) acts in this case on a majority, preferably on all, of the elements within the thermoelectric module.

The above-mentioned features according to the invention may also be provided in combination with one another.

The present invention is applicable to different embodiments of thermoelectric modules. These include, in particular, thermoelectric modules of tubular construction or thermoelectric modules of plate-type construction wherein, for example, in the case of the tubular thermoelectric modules, annular thermoelectric materials may be used.

In particular, the first wall is assigned to a hot side of the thermoelectric module, which is thus impinged on by a hot medium (for example exhaust gas). Correspondingly, the second wall of the thermoelectric module is assigned to a cold side, which is impinged on by a cold medium (for example cooling water). A temperature potential, in particular in a range from 50 K [Kelvin] to 600 K, generally prevails between the hot medium and cold medium during operation. Elements composed of thermoelectric material are disposed between the first wall and the second wall, wherein the thermoelectric materials have two opposite sides which correspondingly face toward the hot side or the cold side, in such a way that a temperature potential forms across the thermoelectric material, and correspondingly, a main heat flow direction is generated from the hot side to the cold side. Due to the Seebeck effect, an electrical current is generated within the thermoelectric module from the temperature potential and due to the alternating electrically conductive connection of the n-doped and p-doped thermoelectric materials. The basic structure of the electrical interconnection of such elements composed of thermoelectric material is known to a person skilled in the art. If necessary, further information in this regard may be gathered from the prior publications of the Applicant, Emitec Gesellschaft für Emissionstechnologie mbH of Lohmar, Germany.

The filler material between the thermoelectric elements serves firstly, in particular, for the electrical insulation of the mutually adjacently disposed thermoelectric materials and/or secondly for thermal insulation between the hot side and the cold side, in such a way that a major part of the heat flow is conducted through the thermoelectric elements. Efficient conversion of the thermal energy from the available temperature potential into electrical energy is thus possible.

Secondly, the filler material is provided, in particular, for spacing the mutually adjacently disposed thermoelectric materials apart from one another, or in other words also for keeping the thermoelectric materials at a (predefined) distance under all operating conditions. In particular, the filler material is thus not formed by air or a vacuum but by at least one solid body which permanently fixes the position of the thermoelectric materials relative to one another. Further components or connecting layers may be disposed between the thermoelectric materials and the first wall and/or the second wall and/or also between the thermoelectric materials and the filler material. The further components or connecting layers perform specific tasks such as, for example, the prevention of corrosion, the generation of a fixed (for example cohesive) connection, the provision of an electrically conductive layer, the provision of a thermally conductive layer, electrical insulation and/or thermal insulation.

Mica or a pressure-resistant ceramic may be used, in particular, as the filler material. The ceramic used is preferably in the form of a ceramic hollow body. Furthermore, the filler material used may be in the shape of a double-T-shaped profile. The filler material used is preferably in the form of a dimensionally rigid structure, in particular in the form of a framework-like construction. The cavities provided therein are filled in particular with air, gas or a vacuum.

It has now been observed that, due to the thermal loading caused by the prevailing temperature potential and, in particular, due to the associated thermal stresses, the thermoelectric material exhibits an increased tendency for transverse contraction and/or a tendency for creep or a tendency for plastic deformation which, in each case, leads to a deterioration of the connection between thermoelectric material and further connecting layers, in particular to the first wall and to the second wall. The thermal stresses are caused, in particular, also by the configuration of the thermoelectric materials in a substantially dimensionally stable thermoelectric module, such that the thermoelectric materials can only expand under stress.

The creep tendency/plastic deformation can now be reduced or eliminated, in particular, by virtue of the thermoelectric module being constructed in such a way that, at least in a temperature range from 50° C. to 600° C. [degrees Celsius] at the hot side, a second compressive stress acting on the elements in the main heat flow direction does not exceed a second threshold stress. A second threshold stress is the stress, acting on the thermoelectric materials, at which a plastic deformation of the thermoelectric material that is used commences.

The transverse contraction of the thermoelectric material can now be reduced or eliminated, in particular, by virtue of the thermoelectric module being constructed in such a way that, at least in a temperature range from 50° C. to 600° C. [degrees Celsius] at the hot side, a second compressive stress acting on the elements in the main heat flow direction does not exceed a first threshold stress. A first threshold stress is the stress, acting on the thermoelectric materials, at which an elastic deformation of the thermoelectric material that is used already commences.

Transverse contraction is a phenomenon of the deformation of a solid body with an approximately unchanging volume. It describes the behavior of the solid body under the influence of a tensile force or compressive force (in this case of a second compressive stress). The body reacts with a change in length (in this case a shortening in the main heat flow direction) in the direction of the force (in this case the second compressive stress) and with a decrease or increase in diameter or thickness (in this case extent, that is to say increase of the thickness of the thermoelectric material) perpendicular thereto (in the direction perpendicular to the main heat flow direction). The change in length under uniaxial tension can, in the linearly elastic range, be defined by the simplified Hooke's law. Hooke's law in its simplified form however does not give any information regarding the change in thickness.

In particular, the first threshold stress is (considerably) lower than the second threshold stress.

For such a construction, it is necessary, in particular, for the material for the first wall and/or the second wall to be coordinated with the thermoelectric material and/or the filler material with regard to thermal expansion, thermal conduction and strength. In particular, it may additionally be necessary to adapt the structural configuration of the construction of the thermoelectric module. For example, expansion elements may be provided which permit an elastic deformation of the first wall and/or of the second wall, in such a way that the (second) compressive stress acting on the elements is minimized.

The first and the second threshold stresses are in each case, in particular, specific to the thermoelectric material that is used, and in particular dependent at least on the temperature of the thermoelectric material. Furthermore, the first and the second threshold stresses are dependent on the stress acting on the thermoelectric material oppositely to the direction of expansion (in the case of the first/second threshold stress) or the direction of the creep tendency (in the case of the second threshold stress) of the thermoelectric material. This means, in particular, that the first and the second threshold stress of the thermoelectric material can be influenced (increased) if the first compressive stress acting on the thermoelectric materials is increased. This takes place, in particular, in self-regulating fashion, for example by virtue of the fact that the filler materials between the thermoelectric materials expand, when heated, in the direction perpendicular to the main heat flow direction more intensely than the thermoelectric module as a whole.

The thermoelectric materials mentioned below exhibit, at the stated temperatures and without further compressive loading (for example additionally as a result of the first compressive stress), the following second threshold stresses, upon exceeding which a plastic deformation can be expected:
Pb₂Te₃ (n-doped): 100 N/mm² at room temperature
   40 N/mm² at 300° C.
Pb₂Te₃ (p-doped): no plastic deformation up to 300° C.
BiTe (n-doped or p-doped): 110 N/mm² at room temperature
   30 N/mm² at 250° C.
CoSb₄ (n-doped or p-doped): no plastic deformation up to 300° C.
   300 N/mm² at 500° C.

In a further embodiment of the thermoelectric module, the transverse contraction and/or the creep tendency/plastic deformation can be reduced or eliminated by virtue of the thermoelectric module being acted on with at least a compressive force in such a way that a first compressive stress acts on the elements perpendicular to the main heat flow direction, wherein it is preferable in this case for as far as possible a large number, or even all, of the elements to be acted on with the compressive force. This takes place at least in a range in which the stated temperature potential prevails, in such a way that the first compressive stress then amounts to at least 50% of a second compressive stress in the main heat flow direction.

The second compressive stress is effected, in particular, due to the gap-free configuration of the thermoelectric materials in a direction from the first wall to the second wall, that is to say in the main heat flow direction. The temperature potential results in a thermal expansion of those components of the thermoelectric module which are disposed between the first wall and the second wall, in such a way that a second compressive stress in the main heat flow direction is generated or increased. The second compressive stress counteracts the thermal expansion of the individual components in the main heat flow direction and leads, in particular in the case of the thermoelectric material, to an expansion (as a result of transverse contraction) and/or to a creep tendency in a direction perpendicular to the main heat flow direction. The transverse contraction and/or the creep tendency can surprisingly be reduced or eliminated entirely by the application of at least a first compressive stress perpendicular to the main heat flow direction. In particular, further first compressive stresses should be provided correspondingly in such a way that the transverse contraction and/or the creep tendency is reduced or eliminated entirely in all directions perpendicular to the main heat flow direction. It was thus also identified for the first time that, contrary to the conventional notion of permitting thermal expansion with travel compensation measures, in the case of the thermoelectric module, a type of compressive frame for the elements leads to improved efficiency over the service life.

In accordance with another advantageous feature of the thermoelectric module of the invention, at least in a temperature range from 50° C. to 600° C., the filler material has a greater coefficient of thermal expansion than the thermoelectric material. The filler material is, at least in a direction perpendicular to the main heat flow direction, disposed between the thermoelectric materials in such a way that the thermoelectric materials are supported on one another through the filler material (and if appropriate through further components or connecting layers), that is to say in particular are disposed without a gap from one another in this direction. The filler material thus fixes the thermoelectric materials in their respective position relative to one another. Due to the filler material being configured with a greater coefficient of thermal expansion than the thermoelectric material, it is possible, in the event of the filler material and the further components in the thermoelectric module being heated, for a compressive force or a compressive stress in a direction perpendicular to the main heat flow direction to be generated (for the first time during operation) or (significantly) increased. In particular, it is necessary for this purpose to ensure a substantially dimensionally stable construction of the thermoelectric module in the direction perpendicular to the main heat flow direction. It is then not necessary for the compressive force to be applied externally to the thermoelectric module in such a way that the compressive stress is generated correspondingly within the thermoelectric module so that most (or all) of the elements are acted on with an adequate compressive stress. Instead, the compressive stress can be generated between most (or all) of the elements by using the filler material in interaction with the thermoelectric materials.

In accordance with a further advantageous feature of the thermoelectric module of the invention, at least in a temperature range from 50° C. to 600° C., the filler material exhibits lower thermal conductivity [watt/(meter*Kelvin)] than the thermoelectric material. In particular, the value of the thermal conductivity of the filler material amounts to at most 10%, preferably at most 1%, of the value of the thermoelectric material.

In accordance with an added advantageous feature of the thermoelectric module of the invention, as viewed at least in a direction parallel to the main heat flow direction, the filler material does not completely fill an intermediate space between the first wall and the second wall. It is advantageous, in particular, if the filler material fixes the position of the thermoelectric materials relative to one another but at the same time does not cover the whole of that side surface of the thermoelectric materials which faces in each case toward the adjacently disposed thermoelectric materials. In particular, at most 80%, preferably at most 50% and particularly preferably at most 20% of the side surface is subjected to a compressive stress by the filler material, wherein this need not apply equally to all elements or thermoelectric materials of a single module. The compressive force or the compressive stress is transmitted to the thermoelectric material through the filler material. In particular, the thermal insulation between the first wall and the second wall can be implemented in a particularly advantageous manner through the corresponding configuration of the filler material, and the filler material need not imperatively impart this thermal insulation characteristic. For example, air, a vacuum or some other thermally insulating material may be used in addition to the filler material.

In accordance with an additional advantageous feature of the thermoelectric module of the invention, a bracing device for generating the compressive force on the thermoelectric module in a direction perpendicular to the main heat flow direction is disposed on a cold side. In particular, the configuration includes a bracing device that is connected, for example, to the second wall. The bracing device is, in particular, constructed to be thermally insulated with respect to the first wall. In this way, despite the prevailing temperature potential, the bracing device exhibits low thermal expansion and can ensure the dimensional stability of the thermoelectric module in a direction perpendicular to the main heat flow direction over the temperature range in question. The bracing device may, in particular, be a mechanical or hydraulic device. In particular, the bracing device is formed by a particularly dimensionally rigid construction of the cold side or of the second wall in such a way that, in the temperature range in question, a (substantially uniform or adapted) compressive force with regard to the thermoelectric materials and the filler material can be generated by the bracing device.

In particular, a bracing device is (additionally) provided on the first wall (hot side).

The bracing device may, in particular, include an elastically deformable element which, with progressive deformation, can introduce a correspondingly higher compressive stress into the thermoelectric module. For example, a compression spring may be provided which, with progressive expansion of the thermoelectric module, or with expansion of the elements in a direction perpendicular to the main heat flow direction, generates a correspondingly increasing compressive stress. As a result of the increasing compressive stress, an elastic expansion and/or a plastic deformation of the thermoelectric materials in a direction perpendicular to the main heat flow direction is reduced or prevented.

With the objects of the invention in view, there is furthermore provided a method for operation of a thermoelectric module, which comprises providing the thermoelectric module with a first wall and a second wall and interposed elements which are composed of thermoelectric material and which are connected to one another in electrically conductive fashion. During operation of the thermoelectric module, a temperature potential prevails between the first wall and the second wall and, correspondingly, a main heat flow direction runs from the first wall to the second wall. The method for operation has at least the following steps:
a) generating a temperature potential between the first wall and the second wall;
b) applying at least one compressive force for the generation of a first compressive stress perpendicular to the main heat flow direction, wherein the compressive stress acts at least on a majority of the elements;
c) ensuring that, at least in an operating range in which a temperature potential between the first wall and the second wall is at least 50 Kelvin, the first compressive stress is at least 50% of a second compressive stress in the main heat flow direction, in particular is at least 75% of and preferably is at least equal to a second compressive stress in the main heat flow direction.

The statements made regarding the respective thermoelectric module apply correspondingly to the method for operating a thermoelectric module, and vice versa. In particular, the method described herein according to the invention is suitable for the operation of the thermoelectric module according to the invention in each case.

The generation of the temperature potential according to step a) includes the impingement of a hot medium on the first wall and the impingement of a cold medium on the second wall. In particular, an exhaust gas or a liquid medium should be provided as the hot medium and, for example, water or a similar liquid, or else a gaseous medium, should be provided as the cold medium.

Step b) encompasses the application of at least a compressive force, which may in particular be applied externally to the thermoelectric module by a bracing device or brace and/or may also be generated within the thermoelectric module, for example by corresponding coefficients of expansion of the thermoelectric material and of the filler material.

The ensuring or maintaining of the ratio of the compressive stresses according to step c) encompasses, in particular, the corresponding structural configuration of the thermoelectric module even before the start of operation. In particular, the ensuring step encompasses monitoring and corresponding action in such a way that the first and/or second compressive stress is calculated, measured or determined in some other way and a corresponding first compressive stress is generated. In particular, “ensuring” is also to be understood to mean monitoring, setting and/or adaptation of the compressive force (if appropriate also during operation).

In accordance with another advantageous mode of the method of the invention, the first compressive stress perpendicular to the main heat flow direction is influenced by external regulation of the at least one compressive force. The external regulation may, for example, be realized by way of a bracing device or brace with which a regulable mechanical and/or hydraulic compressive force can be generated.

In accordance with a further advantageous mode of the method of the invention, the first compressive stress is varied in self-regulating fashion. This may be ensured, in particular, through a corresponding configuration of the material characteristics of the thermoelectric material and the filler material. In this case, “self-regulating” means, in particular, that no active external regulation of the compressive stress is performed, and instead, in particular, the construction is configured in such a way that the predefined compressive stress ratio automatically or passively adapts during operation of the thermoelectric module in different temperature ranges. External regulation and self-regulating measures are particularly advantageously combined with one another.

With the objects of the invention in view, there is additionally provided a thermoelectric generator, comprising at least two thermoelectric modules according to the invention, wherein the thermoelectric modules are acted on, by an (in particular single) component of the thermoelectric generator, jointly with at least one compressive force for the generation of a first compressive stress. It is thus particularly advantageously the case that not every individual thermoelectric module of a thermoelectric generator is acted on with a respectively individually generated compressive force, and instead, for example, a common bracing device or brace is structurally constructed in such a way that multiple thermoelectric modules can be correspondingly acted on simultaneously. In particular, multiple thermoelectric modules may also be correspondingly disposed one behind the other in such a way that the compressive force is also transmitted between the thermoelectric modules.

With the objects of the invention in view, there is concomitantly provided a motor vehicle, comprising at least a thermoelectric module according to the invention or a thermoelectric generator according to the invention. In this case, the module and/or the generator may also be constructed for operation with the method described according to the invention.

Other features which are considered as characteristic for the invention are set forth in the appended claims, noting that the features specified individually in the claims may be combined with one another in any desired technologically expedient manner and form further embodiments of the invention. The description, in particular in conjunction with the figures, explains the invention further and specifies supplementary exemplary embodiments of the invention. It is also pointed out that the embodiments described with regard to the thermoelectric module can likewise be applied in a technically expedient manner to the method for operating a thermoelectric module, and vice versa.

Although the invention is illustrated and described herein as embodied in a thermoelectric module, a method for operating the thermoelectric module, a thermoelectric generator and a motor vehicle, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, partly-sectional, side-elevational view of a thermoelectric module;

FIG. 2 is an enlarged, partly-sectional, fragmentary view of the thermoelectric module of FIG. 1;

FIG. 3 is a partly-sectional, side-elevational view of a tubular thermoelectric module;

FIG. 4 is a diagram showing a profile of compressive stress;

FIG. 5 is a side-elevational view of a thermoelectric generator; and

FIG. 6 is a block diagram of a motor vehicle.

### DETAILED DESCRIPTION OF THE INVENTION

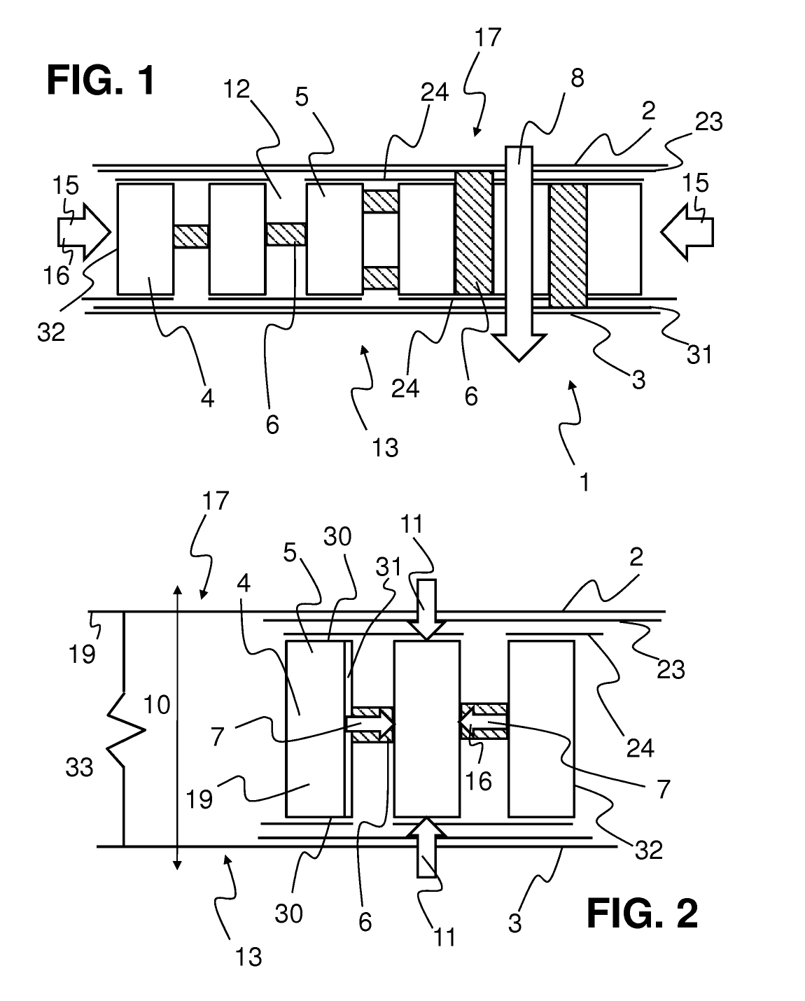

Referring now in detail to the figures of the drawing for explaining the invention and the technical field in more detail by showing particularly preferred structural variants to which the invention is not restricted, and first, particularly, to FIG. 1 thereof, there is seen a side view of a thermoelectric module 1, the outer sides of which are formed by a first wall 2 and a second wall 3. The first wall 2 and the second wall 3 surround an intermediate space 12 in which elements 4 composed of thermoelectric material 5 and further components 19 (insulators 23, connections 24, connecting layers 31, elements 4, etc.) of the thermoelectric module 1 are disposed. The first wall 2 is assigned to a hot side 17, and the oppositely disposed second wall 3 is correspondingly assigned to a cold side 13. The insulators 23 are respectively disposed on the first wall 2 and on the second wall 3, as the connecting layer 31 between the first wall 2 and the thermoelectric materials 5. The mutually adjacently disposed elements 4 composed of thermoelectric materials 5 are connected to one another in electrically conductive fashion and in alternating fashion by the respective connections 24 (conductor tracks, cables, etc.).

The thermoelectric materials 5 are spaced apart from one another by filler materials 6. In this case, different exemplary embodiments of filler materials 6 are shown. In this case, the filler material 6 does not extend over an entire side surface 32 of the thermoelectric material 5, and instead acts on only a sub-region of the side surface 32. If appropriate, multiple filler materials 6 are also provided between mutually adjacently disposed elements 4. Furthermore, filler materials 6 are shown which extend over the entire side surface 32 of the thermoelectric material 5 and furthermore beyond the connection 24 as far as the insulator 23 on the first wall 2 or the second wall 3.

A temperature potential forms between the hot side 17 and the cold side 13, in such a way that a heat flow is generated in a main heat flow direction 8 from the hot side 17 to the cold side 13, preferentially through the thermoelectric materials 5. As a result of the heat flow, due to the Seebeck effect, the thermoelectric materials 5 generate an electrical current which is picked or tapped off through the connections 24, at corresponding electric consumers (battery, electrical consumers, etc.) outside the thermoelectric module 1. The elements 4 are acted on, in a direction 16 perpendicular to the main heat flow direction 8, by a compressive force 15 from outside the thermoelectric module 1.

FIG. 2 shows a portion of FIG. 1, in which elements 4 composed of thermoelectric material 5 are illustrated therein on an enlarged scale. A temperature potential 10 which is generated between the hot side 17 and the cold side 13 in turn generates a heat flow between the hot side 17 and the cold side 13 through the thermoelectric materials 5. The thermoelectric materials 5 are connected to one another in electrically conductive fashion and in alternating fashion by the connections 24 and are separated from the first wall 2 and from the second wall 3 by insulators 23.

The compressive force 15 shown in FIG. 1 generates a first compressive stress 7 by way of the filler material 6 disposed between the thermoelectric materials 5. The first compressive stress 7 acts on the thermoelectric materials 5 in a direction 16 perpendicular to the main heat flow direction 8. Due to the thermal loading, the thermoelectric materials 5 are acted on, in a direction parallel to the main heat flow direction 8, by a second compressive stress 11 which causes an expansion by a transverse contraction and/or creep of the thermoelectric material 5 in the direction 16 perpendicular to the main heat flow direction 8. The filler materials 6 are disposed on the side surface 32 of the thermoelectric material 5. An expansion in a direction 16 perpendicular to the main heat flow direction 8, due to the transverse contraction and/or creep of the thermoelectric material 5, is prevented due to the first compressive stress 7.

It is also shown in FIG. 2 that the second compressive stress 11 can be reduced by using an expansion element 33 in the first wall 2 and/or in the second wall 3 and/or between the first and second walls 2, 3.

It is also shown therein that the side surfaces 32 of the thermoelectric materials 5 may have further connecting layers 31 which, in this case, for example, may be an electrical insulator. It is also shown therein that the thermoelectric materials 5 have two opposite sides 30 which are respectively connected in thermally conductive fashion by using the connection 24 and the insulators 23 to the first wall 2 and the second wall 3.

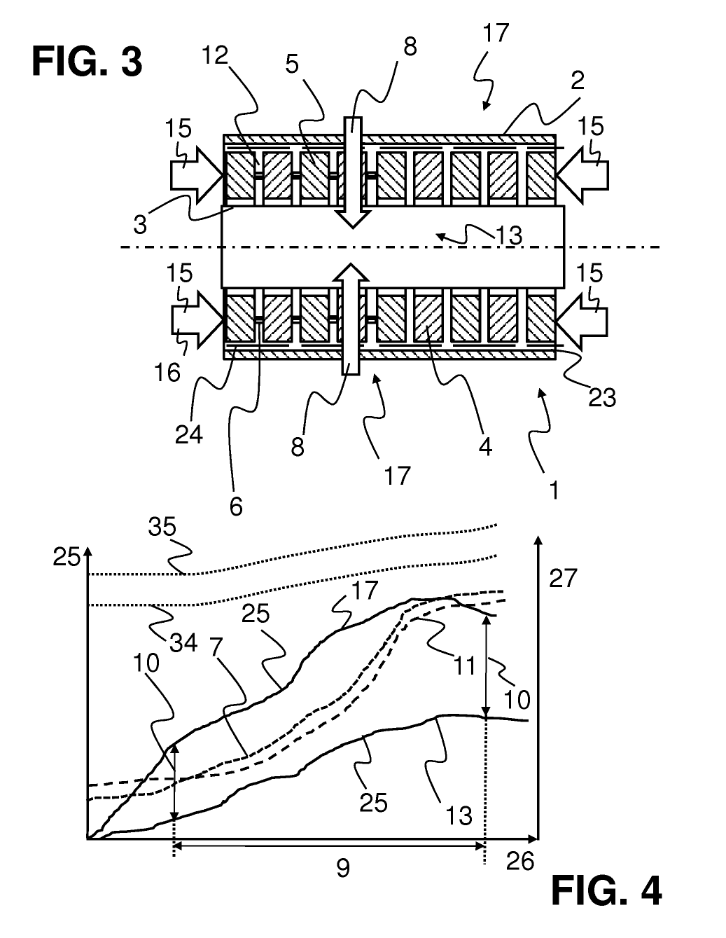

FIG. 3 shows a tubular thermoelectric module 1 with a first wall 2 and a second wall 3. In this case, the second wall 3 forms an inner duct of the tubular thermoelectric module 1. The inner duct in this case is constructed as a cold side 13 through which cooling water, for example, can thus flow. The outer circumferential surface of the thermoelectric module 1, formed by the second wall 2, is constructed as a hot side 17 and can be impinged on, for example, by a flow of hot exhaust gas. A heat flow is generated from the hot side 17 to the cold side 13 in the direction of the main heat flow direction 8. This results in an expansion of the thermoelectric materials 5 in a direction parallel to the main heat flow direction 8 and correspondingly in a second compressive stress 11. The second compressive stress 11 is caused by the different expansions of the individual components 19 of the thermoelectric module 1, for example of the thermoelectric materials 5 and of the first wall 2 and the second wall 3. Now, through the application of a compressive force 15 which generates a first compressive stress 7 between the thermoelectric materials 5, the second compressive stress 11 is compensated insofar as an expansion as a result of transverse contraction and/or creep and/or plastic deformation of the thermoelectric materials 5 in a direction 16 perpendicular to the main heat flow direction 8 does not occur.

FIG. 3 also shows that there are intermediate spaces 12 between the thermoelectric materials 5 and filler materials 6 disposed in the intermediate spaces. The mutually adjacently disposed thermoelectric elements 4 are spaced apart from one another by the intermediate spaces. Furthermore, insulators 23 and connections 24 are provided on each of the first wall 2 and on the second wall 3.

FIG. 4 illustrates the profile of compressive stresses in an operating range of the thermoelectric module 1. The temperature 25 is plotted on the left-hand vertical axis, and the magnitude of the compressive stress 27 is plotted on the right-hand vertical axis. The horizontal axis describes the operating time 26. It can be seen that, with progressive operating time 26, the temperature 25 at the hot side 17 rises, and/or assumes a specific profile. Correspondingly, as a result of the main heat flow, the temperature 25 at the cold side 13 of the thermoelectric module 1 also rises. A temperature potential 10 is generated in an operating range 9 shown on the horizontal axis. In the operating range 9, a second compressive stress 11 that acts on the thermoelectric materials 5 in a direction parallel to the main heat flow direction 8 is lower than a first compressive stress 7 that acts on the thermoelectric materials 5 in a direction 16 perpendicular to the main heat flow direction 8. The tendency of the elements 4 to expand as a result of transverse contraction (in the event of exceeding the first threshold stress 34) or as a result of plastic deformation (in the event of exceeding the second threshold stress 35) in a direction perpendicular to the main heat flow direction 8 is reduced or eliminated as a result of the elements 4 being acted on by the second compressive stress 11. The “bracing” of the thermoelectric elements 4 serves, in particular, to prevent the first threshold stress 34 and/or the second threshold stress 35 of the thermoelectric material from being exceeded.

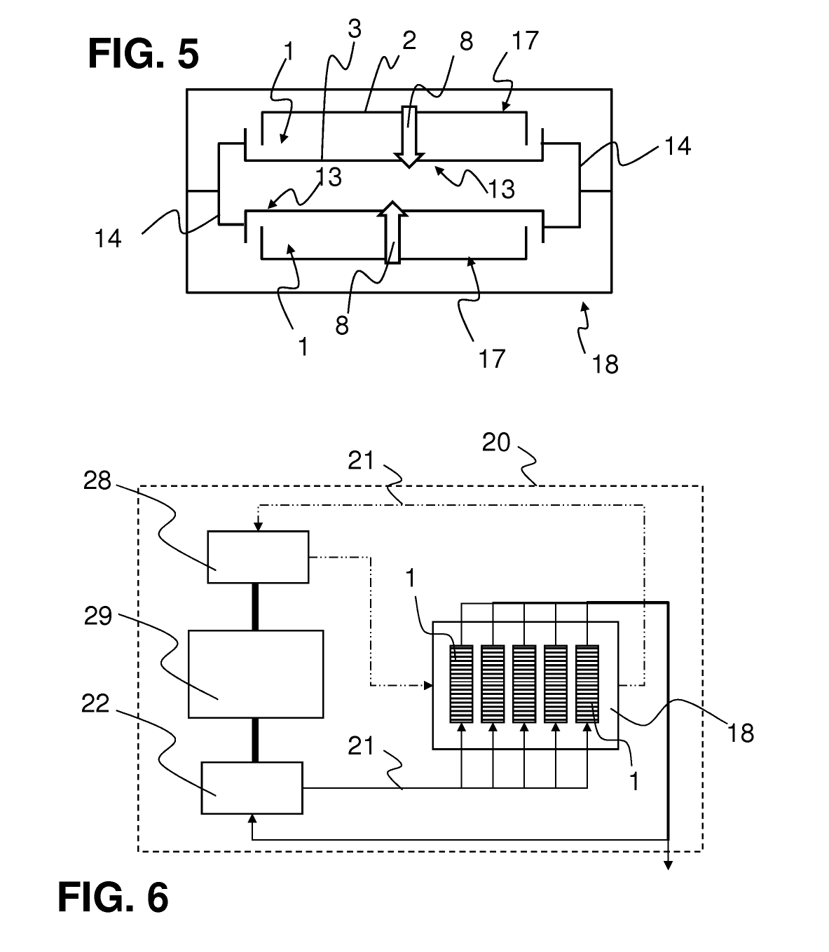

FIG. 5 shows a thermoelectric generator 18 with two thermoelectric modules 1. The thermoelectric modules each have a hot side 17 and a cold side 13, between which a heat flow is generated in a main heat flow direction 8. The thermoelectric modules 1 have a bracing device or brace 14 on their respective cold side 13 or on their second wall 3 that forms the cold side 13. The bracing device 14 is supported on the thermoelectric generator 18 or on the housing thereof and likewise acts on the respective cold side 13 of the two thermoelectric modules 1.

FIG. 6 shows a motor vehicle 20 having an internal combustion engine 29, a cooling configuration or cooler 28 and an exhaust system or line 22. A cold medium 21 from the cooling configuration 28 flows through thermoelectric modules 1 that are disposed within a thermoelectric generator 18. Furthermore, a hot medium 21 from the internal combustion engine 29, or from the exhaust system 22, flows through the thermoelectric modules 1. Due to the impingement on the thermoelectric modules 1 of an exhaust gas, as the hot medium 21, and of a cooling liquid, as the cold medium 21, a temperature potential is generated across the thermoelectric modules, in such a way that an electrical current can be generated in the thermoelectric generator 18.

1. A thermoelectric module, comprising:
a first wall forming a hot side;
a second wall disposed opposite said first wall;
elements formed of thermoelectric material disposed between said first and second walls, said elements being electrically conductively connected to one another;
a filler material spacing all of said elements apart from one another;
a main heat flow direction running from said hot side formed by said first wall to said second wall;
said elements being acted on in said main heat flow direction by a second compressive stress having a first threshold stress and a second threshold stress;
said thermoelectric material commencing to transversely contract upon exceeding said first threshold stress;
said thermoelectric material commencing to plastically deform upon exceeding said second threshold stress; and
during operation of the thermoelectric module at least in a temperature range between 50 and 600° C. at said hot side, said second compressive stress not exceeding at least said first threshold stress, or said second compressive stress not exceeding at least said second threshold stress.

2. The thermoelectric module according to claim 1, wherein said filler material has a greater coefficient of thermal expansion than said thermoelectric material at least in a temperature range from 50 to 600° C.

3. The thermoelectric module according to claim 1, wherein said filler material exhibits lower thermal conductivity [watt/(meter*kelvin)] than said thermoelectric material at least in a temperature range from 50 to 600° C.

4. The thermoelectric module according to claim 1, wherein said first and second walls define an intermediate space therebetween, and said filler material does not completely fill said intermediate space in a direction parallel to said main heat flow direction.

5. The thermoelectric module according to claim 1, which further comprises:
a cold side; and
a bracing device disposed on said cold side and configured to generate a compressive force on said thermoelectric module in a direction perpendicular to said main heat flow direction.

6. A thermoelectric module, comprising:
a first wall and a second wall disposed opposite each other and defining a temperature potential between said first wall and said second wall;
elements formed of thermoelectric material disposed between said first and second walls, said elements being are electrically conductively connected to one another;
a filler material spacing all of said elements apart from one another;
a main heat flow direction running from said first wall to said second wall and defining a first compressive stress perpendicular to said main heat flow direction and a second compressive stress in said main heat flow direction; and
the thermoelectric module being braced by at least one compressive force causing said first compressive stress to be at least 50% of said second compressive stress at least in a range in which said temperature potential is at least 50 Kelvin.

7. The thermoelectric module according to claim 2, wherein said first and second walls define an intermediate space therebetween, and said filler material does not completely fill said intermediate space in a direction parallel to said main heat flow direction.

8. The thermoelectric module according to claim 2, which further comprises:
a cold side; and
a bracing device disposed on said cold side and configured to generate said at least one compressive force on the thermoelectric module in a direction perpendicular to said main heat flow direction.

9. A method for operating a thermoelectric module, the method comprising the following steps:
providing a thermoelectric module having a first wall, a second wall, elements formed of thermoelectric material being electrically conductively connected to one another and disposed between the first and second walls, the first and second walls defining, during operation, a temperature potential prevailing between the first wall and the second wall and a main heat flow direction running from the first wall to the second wall;
a) generating a temperature potential between the first wall and the second wall;
b) applying at least one compressive force generating a first compressive stress acting perpendicular to the main heat flow direction and acting at least on a majority of the elements; and
c) maintaining the first compressive stress at least at 50% of a second compressive stress in the main heat flow direction at least in a range of the temperature potential of at least 50 Kelvin.

10. The method according to claim 7, which further comprises influencing the first compressive stress perpendicular to the main heat flow direction by external regulation of the at least one compressive force.

11. The method according to claim 7, which further comprises varying the first compressive stress in a self-regulating manner.

12. A thermoelectric generator, comprising:
two thermoelectric modules according to claim 1; and
a component acting on said thermoelectric modules jointly with at least one compressive force for generating a first compressive stress.

13. A thermoelectric generator, comprising:
two thermoelectric modules according to claim 2; and
a component acting on said thermoelectric modules jointly with said at least one compressive force for generating said first compressive stress.

14. A motor vehicle, comprising a thermoelectric module according to claim 1.

15. A motor vehicle, comprising:
a thermoelectric generator having two thermoelectric modules according to claim 1, and a component acting on said thermoelectric modules jointly with at least one compressive force for generating a first compressive stress.

16. A motor vehicle, comprising:
a thermoelectric generator having two thermoelectric modules according to claim 2, and a component acting on said thermoelectric modules jointly with said at least one compressive force for generating said first compressive stress.
